(19) United States
(12) Patent Application Publication
(10) Pub. No.: US 2009/0001591 A1
(43) Pub. Date: Jan. 1, 2009

(54) REDUCING RESISTIVITY IN METAL INTERCONNECTS BY COMPRESSIVE STRAINING

(76) Inventors: Michael Haverty, Mountain View, CA (US); Sadasivan Shankar, Cupertino, CA (US); Kevin O'Brien, Portland, OR (US); Seongjun Park, San Jose, CA (US)

Correspondence Address: COOL PATENT, P.C.;c/o INTELLEVATE, P.O. BOX 52050, MINNEAPOLIS, MN, 55402, US

(21) Appl. No.: 11/771,476

(22) Filed: Jun. 29, 2007

(51) Int. Cl. H01L 23/52; H01L 21/4763

(52) U.S. Cl. 257/762; 438/643; 257/E23.141; 257/E21.495

(57) ABSTRACT

Techniques for reducing resistivity in metal interconnects by compressive straining are generally described. In one example, an apparatus includes a dielectric substrate, a thin film of metal coupled with the dielectric substrate, and an interconnect metal coupled to the thin film of metal, the thin film of metal having a lattice parameter that is smaller than the lattice parameter of the interconnect metal to compressively strain the interconnect metal.

### TECHNICAL FIELD

Embodiments disclosed herein are generally directed to the field of semiconductor fabrication and, more particularly, to reducing resistivity in metal interconnects.

### BACKGROUND

Generally, power required by an integrated circuit (IC) is proportional to the resistance of the circuit. In addition, signal delay such as resistive capacitive (RC) delay is limited by interconnect resistance. Problems associated with power consumption and signal delay are exacerbated as interconnect line widths are reduced. For example, the scaling of microelectronic circuits may reduce the thickness (t) of metal lines, which may increase the resistivity and resistance of metal lines in a roughly 1/t fashion. Decreasing the resistance and resistivity of circuit materials may reduce power consumption and increase the speed at which a circuit switches.

### BRIEF DESCRIPTION OF THE DRAWINGS

Embodiments disclosed herein are illustrated by way of example, and not by way of limitation, in the figures of the accompanying drawings in which like reference numerals refer to similar elements and in which:

FIG. 1 is a schematic of a microelectronic apparatus including a compressively strained interconnect, according to but one embodiment;

FIG. 2 is a flow diagram of a method to compressively strain an interconnect metal, according to but one embodiment; and

FIG. 3 is a diagram of an example system in which embodiments disclosed herein may be used, according to but one embodiment.

It will be appreciated that for simplicity and/or clarity of illustration, elements illustrated in the figures have not necessarily been drawn to scale. For example, the dimensions of some of the elements may be exaggerated relative to other elements for clarity. Further, if considered appropriate, reference numerals have been repeated among the figures to indicate corresponding and/or analogous elements.

### DETAILED DESCRIPTION

Embodiments of reducing resistivity in metal interconnects by compressive straining are described herein. In the following description, numerous specific details are set forth to provide a thorough understanding of embodiments disclosed herein. One skilled in the relevant art will recognize, however, that the embodiments disclosed herein can be practiced without one or more of the specific details, or with other methods, components, materials, and so forth. In other instances, well-known structures, materials, or operations are not shown or described in detail to avoid obscuring aspects of the specification.

Reference throughout this specification to “one embodiment” or “an embodiment” means that a particular feature, structure or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

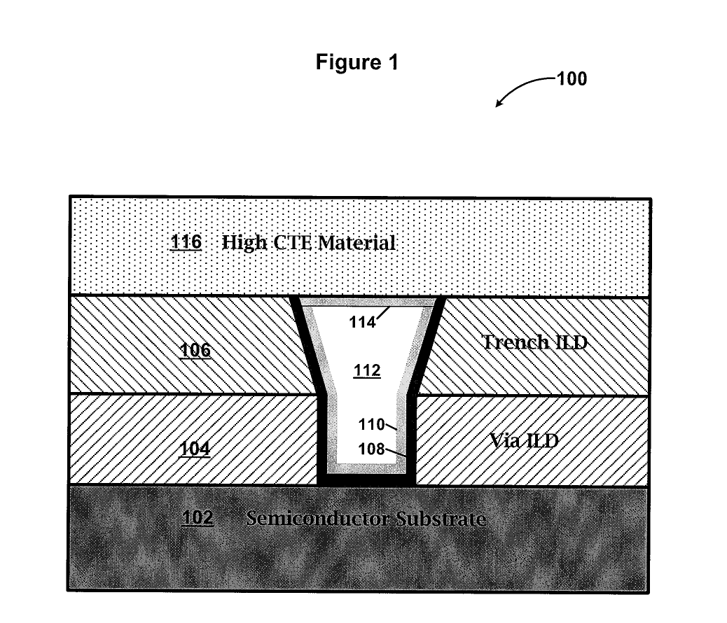

FIG. 1 is a schematic of a microelectronic apparatus 100 including a compressively strained interconnect, according to but one embodiment. In an embodiment, apparatus 100 includes a semiconductor substrate 102, via inter-layer dielectric (ILD) 104, trench ILD 106, barrier film 108, thin film of metal 110, interconnect metal 112, capping film of metal 114, and high coefficient of thermal expansion (CTE) material 116, each coupled as shown.

Applying a compressive strain to a metal interconnect 112 may reduce the resistivity of the metal interconnect 112 by changing its band structure. Resistivity may depend on the number of states for scattering near the Fermi energy of an interconnect metal 112. Straining the interconnect metal 112 may reduce the number of states available for scattering near the Fermi energy, reducing the resistivity of the interconnect metal 112. In this regard, a compressive strain may change the electronic structure of interconnect metal 112 at the interface between the interconnect metal 112 and a thin metal film 114, 110 and reduce scattering in the underlying crystal structure of the interconnect metal 112. In one embodiment, it is the strained interface region that results in a decrease in resistivity of a metal interconnect 112. A variety of techniques for reducing resistivity by applying a compressive strain to a metal interconnect 112 are disclosed herein.

In an embodiment, compressive straining of an interconnect metal 112 comprising Cu reduces the scattering rates due to the lower density of state (DOS) near the Fermi Energy. This effect may be more evident in certain crystalline directions than others, the directions being defined as (xyz), where x, y, and z are crystallographic planes that are perpendicular to one another. In one example embodiment, the effect is more evident in the (100) direction than the (110) direction. In another embodiment, a compressive strain on Cu 112 in either the (111), (110), or (100) directions reduces the resistivity of Cu 112 by an amount on the order of the induced strain. For example, applying a 5% compressive strain on Cu (100) may reduce the resistivity by approximately 11%. In another embodiment, the proportion of Cu (110) surfaces at room temperature increases above the proportion of Cu (111) as Cu is strained due to the relative difference of surface energy of Cu (110) and (100) reducing compared to Cu (111). Such embodiment may suggest that Cu be held in its strained condition by an external force such as an epitaxial underlayer or constraining capping layer as later described, to prevent relaxing or kinetic annealing to the lower energy state, but higher resistivity Cu surfaces. In an embodiment, interconnect metal 112 comprises a Cu (111) orientation equal to or greater than about 80% in proportion to other orientations.

In an embodiment, compressive straining of interconnect 112 may be defined by the following film/substrate strain relationship where ε is strain, a is the lattice parameter, and t is thickness:

ε_{interconnect}=((a_{adjacent film}−a_{interconnect})/a_{interconnect})·(t_{adjacent film}/(t_{adjacent film}+t_{interconnect}))

In this regard, different compressive strains can be selectively applied that depend on the lattice mismatch and thickness of an adjacent metal film 110, 114 with an interconnect metal 112. In an embodiment, apparatus 100 includes a dielectric substrate 104, 106, a thin film of metal 114 coupled with the dielectric substrate 104, 106, and an interconnect metal 112 coupled to the thin film of metal 114, the thin film of metal 114 having a lattice parameter that is smaller than the lattice parameter of the interconnect metal 112 to compressively strain the interconnect metal 112. The lattice parameter for Cu may be about 3.62 angstroms.

In an embodiment, a thin film of metal 114 caps an interconnect metal 112 as depicted. In another embodiment, a thin film of metal 114 is Ni and an interconnect metal 112 is Cu. In another embodiment, a thin film of metal 114 is deposited to cap the interconnect metal 112 using an electroless deposition process. In another embodiment, thin film of metal 114 is deposited to cap the interconnect metal 112 using an epitaxial deposition process. Capping the interconnect metal 112 may also provide a benefit of reducing electromigration of interconnect metal 112.

In an embodiment, apparatus 100 includes a dielectric substrate 104, 106, a thin film of metal 110 coupled with the dielectric substrate 104, 106, and an interconnect metal 112 coupled to the thin film of metal 110, the thin film of metal 110 having a lattice parameter that is smaller than the lattice parameter of the interconnect metal 112 to compressively strain the interconnect metal 112. In an embodiment, the interconnect metal 112 is epitaxially deposited to the thin film of metal 110. In other embodiments, the interconnect metal 112 is deposited to the thin film of metal 110 using atomic layer deposition (ALD), crystal growth, physical vapor deposition (PVD) or any other suitable method that enables a compressive strain to the interconnect metal 112. In another embodiment, a dielectric substrate 104, 106 has one or more patterned trenches (the area deposited with interconnect 112 and films 108, 110 on the same plane as trench ILD 106) and/or vias (the area deposited with interconnect 112 and films 108, 110 on the same plane as via ILD 104).

Another technique for compressively straining an interconnect metal 112 includes deposition of a high coefficient of thermal expansion (CTE) material 116 at elevated temperature to the interconnect metal 112. In one example embodiment, compressive straining of an interconnect metal 112 is caused by a thermal contraction mismatch between the high CTE material 116 and the metal interconnect 112 (i.e.—the high CTE material 116 contracts more during cooling than the metal interconnect 112 imposing a strain at the interface). According to Stoney's formula, where ε is strain, α is CTE, and T is temperature:

ε_{interconnect}=(α_{interconnect}−α_{highCTEmaterial})·ΔT

a material with a CTE of 60 ppm/° C. would result in about a 1% compressive strain on an interconnect 112 comprising Cu when cooled from 250° C. to about room temperature, in an embodiment. In an embodiment, an apparatus 100 comprises a material 116 coupled with an interconnect metal 112, the material 116 having a CTE that is larger than the CTE of the interconnect metal 112 to compressively strain the interconnect metal. In an embodiment, material 116 includes aluminum. In an embodiment, material 116 is a high CTE dielectric and interconnect metal 112 is Cu having a CTE of about 16-17 ppm/° C. In another embodiment, a high CTE material includes any suitable material having a CTE greater than about 30 ppm/° C. In another embodiment, material 116 includes, but is not limited to, SiLK® (a registered trademark of Dow Chemical), fluorine containing carbon polymers, polypropylene, phenolic resin, and/or polymer blends having a CTE greater than about 30 ppm/° C., or suitable combinations thereof. Dielectric materials 116 may be deposited by an electroless deposition. An elevated temperature for deposition of material 116 may be a temperature above about room temperature that provides a desired compressive straining upon cooling to about room temperature according to the interconnect metal 112 and material 116 used.

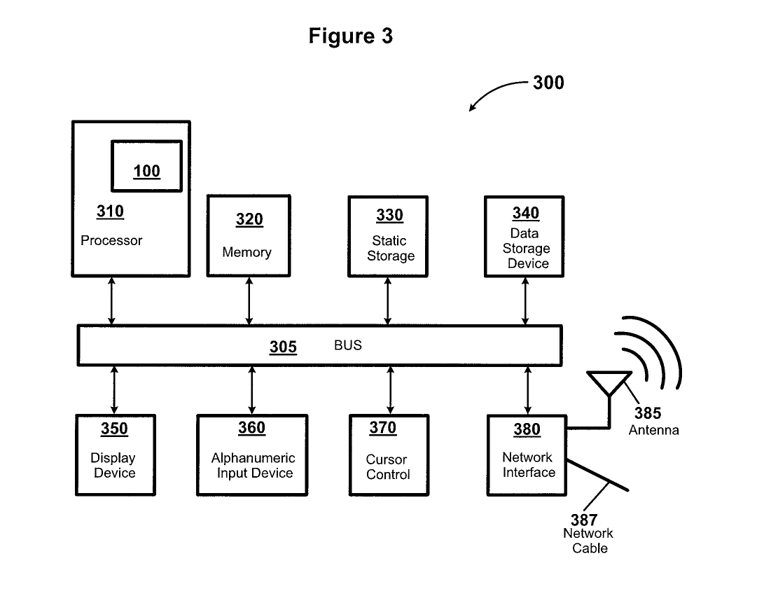

In another embodiment, interconnect metal 112 is an interconnect of an integrated circuit, the interconnect metal having a thickness of about 60 nm or less. In another embodiment, one or more electronic systems are coupled with the integrated circuit comprising interconnect 112. Other electronic elements, components, and/or systems may be coupled with an apparatus 100 that accords with embodiments described herein. An example of such a system is shown and described with respect to FIG. 3.

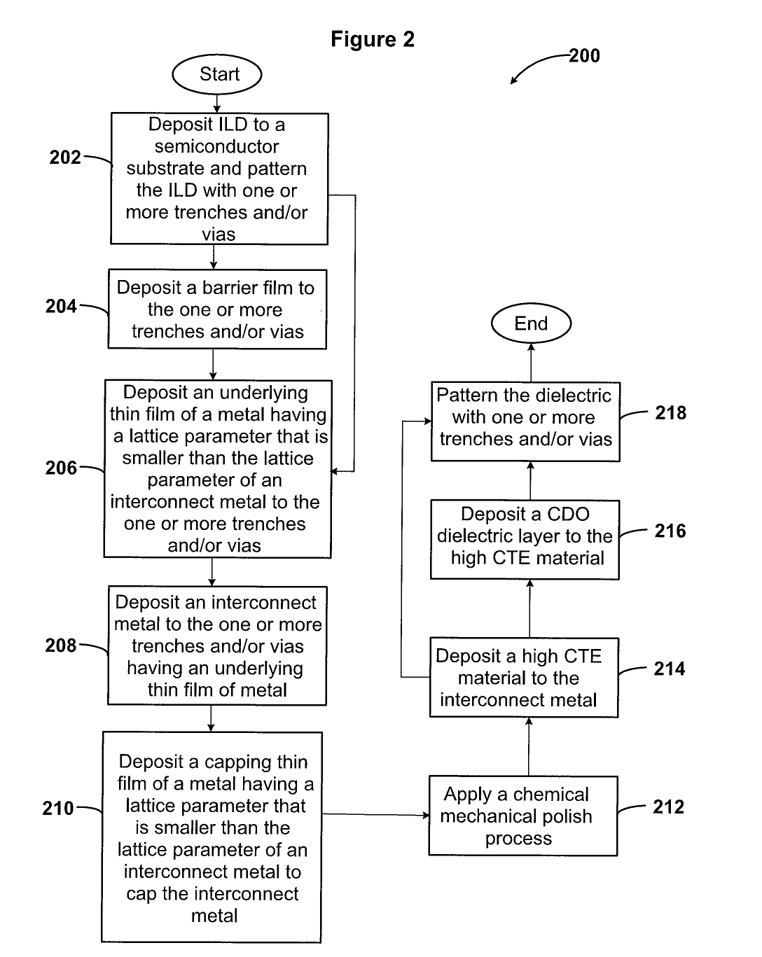

FIG. 2 is a flow diagram of a method 200 to compressively strain an interconnect metal, according to but one embodiment. In an embodiment, a method 200 includes depositing one or more inter-layer dielectric layers (ILD) to a semiconductor substrate and patterning the ILD with one or more trenches and/or vias 202, depositing a barrier film to the one or more trenches and/or vias 204, depositing an underlying thin film of a metal having a lattice parameter that is smaller than the lattice parameter of an interconnect metal to the one or more trenches and/or vias 206, depositing an interconnect metal to the one or more trenches and/or vias having an underlying thin film of metal 208, depositing a capping thin film of a metal having a lattice parameter that is smaller than the lattice parameter of an interconnect metal to cap the interconnect metal 210, applying a chemical mechanical polish process 212, depositing a high CTE material to the interconnect metal 214, depositing a carbon-doped oxide (CDO) dielectric layer to the high CTE material 216, and patterning the dielectric with one or more trenches and/or vias, with arrows providing a suggested flow. Although arrows may suggest some alternative flows, other flows may be enabled by this description that are different from what is depicted in the flow diagram for method 200.

In an embodiment, a method 200 includes various techniques to compressively strain an interconnect metal including depositing an underlying thin film of a metal to one or more trenches 206, depositing an interconnect metal to one or more trenches and/or vias having an underlying thin film of metal 208, depositing a capping thin film of a metal to cap the interconnect material 210, and depositing a high CTE material to the interconnect metal 214. Depositions described for 206, 208, 210, and 214 may be performed alone and/or in combination to compressively strain an interconnect metal.

In an embodiment, a method 200 includes preparing a dielectric substrate for deposition of an interconnect metal 202, 204, 206, depositing an interconnect metal to one or more trenches and/or vias patterned into a dielectric substrate 208, and depositing a capping thin film of a metal to cap the interconnect metal, the capping thin film having a lattice parameter that is smaller than the lattice parameter of the interconnect metal to compressively strain the interconnect metal 210. In an embodiment, the capping thin film of a metal includes Ni and the interconnect metal includes Cu. In another embodiment, the interconnect metal includes Cu having a Cu (111) orientation equal to or greater than about 80%. In another embodiment, deposition of a capping thin film of a metal to cap the interconnect metal 210 includes using an electroless deposition method.

In an embodiment, preparing a dielectric substrate for deposition of an interconnect metal includes depositing a dielectric layer to a semiconductor substrate and patterning the dielectric layer with one or more trenches and/or vias 202. In another embodiment, preparing a dielectric substrate for deposition of an interconnect metal includes depositing a barrier film to the one or more trenches and/or vias 204. In an embodiment, preparing a dielectric substrate for deposition of an interconnect metal includes depositing an underlying thin film of a metal to one or more vias or trenches 206. In an embodiment, the term “underlying” refers to a temporal relationship; for example, the underlying thin film is deposited prior to the deposition of an interconnect metal. The term “underlying” does not necessarily imply any particular physical orientation in this regard. In an embodiment, the underlying thin film of a metal comprises Ni and the interconnect metal comprises Cu. In another embodiment the interconnect metal includes Cu having a Cu (111) orientation equal to or greater than about 80%. In another embodiment, depositing an interconnect metal to the one or more trenches and/or vias 208 includes using an epitaxial deposition method.

In an alternative embodiment, depositing a barrier film 204 is not necessary because depositing the underlying thin film of a metal 206 includes a material that provides a film with sufficient diffusion barrier properties.

In an embodiment, a method 200 includes depositing material having a high coefficient of thermal expansion (CTE) at an elevated temperature to cap the interconnect metal 214, the high CTE material having a coefficient of thermal expansion that is larger than the coefficient of thermal expansion of the interconnect metal to compressively strain the interconnect metal. In an embodiment, the interconnect metal is Cu. In another embodiment, the elevated temperature is greater than or equal to about 200° C. In yet another embodiment, a high CTE material includes any suitable material having a CTE greater than about 30 ppm/° C. A high CTE material includes Al, SiLK®, fluorine containing carbon polymers, Polypropylene, or polymer blends having a CTE greater than about 30 ppm/° C., or suitable combinations thereof, but is not limited to these examples.

A method 200 includes applying a chemical mechanical polish 212 to the dielectric substrate prior to depositing a high CTE material 214 according to an embodiment. Another embodiment includes depositing a dielectric layer to the high CTE material 216. The dielectric layer may be a carbon-doped oxide (CDO). Another embodiment includes patterning the dielectric layer and the high CTE material with one or more trenches and/or vias. In an embodiment, depositing a CDO dielectric layer 216 may not be necessary because a high CTE material may be selected to be a suitable replacement for a current dielectric such as CDO. In such embodiment, a high CTE material may be a dielectric material that is patterned with one or more trenches and/or vias 218. In an embodiment, a stack of metal interconnects are built upon one another by repeating the enumerated processes from 204 to 218 according to a selected flow based on embodiments described herein.

In other embodiments, one or more disclosed techniques are combined in any suitable manner to compressively strain interconnect metal 112. Method 200 also incorporates embodiments already described with respect to an apparatus 100 in FIG. 1. Various operations may be described as multiple discrete operations in turn, in a manner that is most helpful in understanding the embodiments disclosed herein. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

FIG. 3 is a diagram of an example system in which embodiments disclosed herein may be used, according to but one embodiment. System 300 is intended to represent a range of electronic systems (either wired or wireless) including, for example, desktop computer systems, laptop computer systems, personal computers (PC), wireless telephones, personal digital assistants (PDA) including cellular-enabled PDAs, set top boxes, pocket PCs, tablet PCs, DVD players, or servers, but is not limited to these examples and may include other electronic systems. Alternative electronic systems may include more, fewer and/or different components.

In one embodiment, electronic system 300 includes a compressively strained interconnect 100 that accords with embodiments described with respect to FIG. 1. In an embodiment, a compressively strained interconnect 100 is part of an integrated circuit (IC) such as a processor 310. In an embodiment, the IC incorporating apparatus 100 is coupled with one or more electronic systems 300. In other embodiments, electronic system 300 is coupled with an interconnect apparatus 100 that accords with embodiments already described for FIGS. 1-2.

Electronic system 300 may include bus 305 or other communication device to communicate information, and processor 310 coupled to bus 305 that may process information. While electronic system 300 is illustrated with a single processor, system 300 may include multiple processors and/or co-processors. System 300 may also include random access memory (RAM) or other storage device 320 (may be referred to as memory), coupled to bus 305 and may store information and instructions that may be executed by processor 310.

Memory 320 may also be used to store temporary variables or other intermediate information during execution of instructions by processor 310. Memory 320 is a flash memory device in one embodiment.

System 300 may also include read only memory (ROM) and/or other static storage device 330 coupled to bus 305 that may store static information and instructions for processor 310. Data storage device 340 may be coupled to bus 305 to store information and instructions. Data storage device 340 such as a magnetic disk or optical disc and corresponding drive may be coupled with electronic system 300.

Electronic system 300 may also be coupled via bus 305 to display device 350, such as a cathode ray tube (CRT) or liquid crystal display (LCD), to display information to a user. Alphanumeric input device 360, including alphanumeric and other keys, may be coupled to bus 305 to communicate information and command selections to processor 310. Another type of user input device is cursor control 370, such as a mouse, a trackball, or cursor direction keys to communicate information and command selections to processor 310 and to control cursor movement on display 350.

Electronic system 300 further may include one or more network interfaces 380 to provide access to network, such as a local area network. Network interface 380 may include, for example, a wireless network interface having antenna 385, which may represent one or more antennae. Network interface 380 may also include, for example, a wired network interface to communicate with remote devices via network cable 387, which may be, for example, an Ethernet cable, a coaxial cable, a fiber optic cable, a serial cable, or a parallel cable.

In one embodiment, network interface 380 may provide access to a local area network, for example, by conforming to an Institute of Electrical and Electronics Engineers (IEEE) standard such as IEEE 802.11b and/or IEEE 802.11g standards, and/or the wireless network interface may provide access to a personal area network, for example, by conforming to Bluetooth standards. Other wireless network interfaces and/or protocols can also be supported.

IEEE 802.11b corresponds to IEEE Std. 802.11b-1999 entitled “Local and Metropolitan Area Networks, Part 11: Wireless LAN Medium Access Control (MAC) and Physical Layer (PHY) Specifications: Higher-Speed Physical Layer Extension in the 2.4 GHz Band,” approved Sep. 16, 1999 as well as related documents. IEEE 802.11g corresponds to IEEE Std. 802.11g-2003 entitled “Local and Metropolitan Area Networks, Part 11: Wireless LAN Medium Access Control (MAC) and Physical Layer (PHY) Specifications, Amendment 4: Further Higher Rate Extension in the 2.4 GHz Band,” approved Jun. 27, 2003 as well as related documents. Bluetooth protocols are described in “Specification of the Bluetooth System: Core, Version 1.1,” published Feb. 22, 2001 by the Bluetooth Special Interest Group, Inc. Previous or subsequent versions of the Bluetooth standard may also be supported.

In addition to, or instead of, communication via wireless LAN standards, network interface(s) 380 may provide wireless communications using, for example, Time Division, Multiple Access (TDMA) protocols, Global System for Mobile Communications (GSM) protocols, Code Division, Multiple Access (CDMA) protocols, and/or any other type of wireless communications protocol.

In an embodiment, a system 300 includes one or more omnidirectional antennae 385, which may refer to an antenna that is at least partially omnidirectional and/or substantially omnidirectional, a processor 310 coupled to communicate via the antennae, the processor including a compressively strained interconnect 100 as described herein.

The above description of illustrated embodiments, including what is described in the Abstract, is not intended to be exhaustive or to limit to the precise forms disclosed. While specific embodiments and examples are described herein for illustrative purposes, various equivalent modifications are possible within the scope of this description, as those skilled in the relevant art will recognize.

These modifications can be made in light of the above detailed description. The terms used in the following claims should not be construed to limit the scope to the specific embodiments disclosed in the specification and the claims. Rather, the scope of the embodiments disclosed herein is to be determined entirely by the following claims, which are to be construed in accordance with established doctrines of claim interpretation.

What is claimed is:

1. An apparatus comprising:
a dielectric substrate;
a thin film of metal coupled with the dielectric substrate; and
an interconnect metal coupled to the thin film of metal, the thin film of metal having a lattice parameter that is smaller than a lattice parameter of the interconnect metal to compressively strain the interconnect metal.

2. An apparatus according to claim 1 wherein the thin film of metal comprises Ni and the interconnect metal comprises Cu having a Cu (111) orientation equal to or greater than about 80%.

3. An apparatus according to claim 1 wherein the thin film of metal is electrolessly deposited to cap the interconnect metal.

4. An apparatus according to claim 1 wherein the interconnect metal is epitaxially deposited to the thin film of metal.

5. An apparatus according to claim 1 further comprising a material coupled with the interconnect metal, the material having a coefficient of thermal expansion (CTE) that is larger than a CTE of the interconnect metal to compressively strain the interconnect metal.

6. An apparatus according to claim 5 wherein the material comprises Al, SiLK®, fluorine containing carbon polymers, polypropylene, phenolic resin, or polymer blends having a CTE greater than about 30 ppm/° C., or suitable combinations thereof.

7. An apparatus according to claim 1 wherein the interconnect metal is an interconnect of an integrated circuit, the interconnect metal having a thickness of about 60 nanometers or less; and
one or more electronic systems coupled with the integrated circuit.

8. A method comprising:
preparing a dielectric substrate for deposition of an interconnect metal;
depositing an interconnect metal to one or more vias or trenches patterned into a dielectric substrate; and
depositing a capping thin film of a metal to cap the interconnect metal, the capping thin film of metal having a lattice parameter that is smaller than a lattice parameter of the interconnect metal to compressively strain the interconnect metal.

9. A method according to claim 8 wherein depositing a capping thin film of a metal comprises depositing a capping thin film comprising Ni using an electroless deposition method and wherein depositing an interconnect metal comprises depositing an interconnect metal comprising Cu having a Cu (111) orientation equal to or greater than about 80%.

10. A method according to claim 8 wherein preparing a dielectric substrate comprises:
depositing an underlying thin film of a metal to one or more vias or trenches prior to depositing the interconnect metal, the underlying thin film of metal having a lattice parameter that is smaller than a lattice parameter of the interconnect metal to compressively strain the interconnect metal.

11. A method according to claim 10 wherein the underlying thin film of a metal comprises Ni and the interconnect metal comprises Cu and wherein depositing an interconnect metal to the one or more trenches or vias having the underlying film of metal is accomplished using an epitaxial deposition method.

12. A method according to claim 8 further comprising:
depositing a material having a high coefficient of thermal expansion (CTE) at an elevated temperature to cap the interconnect metal, the high CTE material having a coefficient of thermal expansion that is larger than a coefficient of thermal expansion of the interconnect metal to compressively strain the interconnect metal.

13. A method according to claim 12 wherein the interconnect metal is Cu, the elevated temperature is greater than or equal to about 200° C., and the high CTE material comprises Al, SiLK®, fluorine containing carbon polymers, Polypropylene, or polymer blends having a CTE greater than about 30 ppm/° C., or suitable combinations thereof.

14. A method according to claim 12 further comprising:
applying a chemical mechanical polish to the dielectric substrate prior to depositing a high CTE material;
depositing a dielectric layer to the high CTE material; and
patterning the dielectric layer and the deposited high CTE material with one or more trenches or vias.

15. A method according to claim 8 wherein preparing a dielectric substrate comprises:
depositing a dielectric layer to a semiconductor substrate;
patterning the dielectric material with one or more trenches or vias; and
depositing a barrier film to the one or more trenches or vias.
